(19) United States
(12) Patent Application Publication
(10) Pub. No.: US 2026/0079183 A1
(43) Pub. Date: Mar. 19, 2026

(54) CURRENT DETECTION APPARATUS

(71) Applicant: HONDA MOTOR CO., LTD., Tokyo (JP)

(72) Inventors: Shotaro KARASUYAMA, Tokyo (JP); Kosuke KAJITA, Tokyo (JP); Jiro FUKUI, Tokyo (JP)

(21) Appl. No.: 19/329,580

(22) Filed: Sep. 16, 2025

(30) Foreign Application Priority Data
Sep. 18, 2024 (JP) 2024-161367

(51) Int. Cl. G01R 15/20; G01R 19/00; G01R 31/34

(52) U.S. Cl. CPC G01R 15/20; G01R 19/0092; G01R 31/34

(57) ABSTRACT

A current detection apparatus 3 detects currents flowing through bus bars 6u, 6v, and 6w of a motor M, and includes: a first magnetic detection element 81, a second magnetic detection element 82, and a third magnetic detection element 83 provided around the bus bars 6u, 6v, and 6w; a magnetic sensitivity coefficient storage unit 23 storing values of a plurality of magnetic sensitivity coefficients; and the two-phase current values calculation unit 22 calculating two-phase current values based on output values Sₓ, S_{y}, and S_{z} of the magnetic detection elements 81, 82, and 83, and the values of the plurality of magnetic sensitivity coefficients. The position of a detection center of the first magnetic detection element 81 and the orientation of a detection axis of the first magnetic detection element 81 are determined such that the output value Sₓ is proportional to an α-phase current value.

This application is based on and claims the benefit of priority from Japanese Patent Application No. 2024-161367, filed on 18 Sep. 2024, the content of which is incorporated herein by reference.

### BACKGROUND OF THE INVENTION

### Field of the Invention

The present invention relates to a current detection apparatus. More specifically, the present invention relates to a current detection apparatus for detecting a current of each phase of a three-phase motor based on at least two magnetic detection elements.

### Related Art

Recently, initiatives to realize a low-carbon or carbon-free society have been active, and, for vehicles, research and development for electric vehicles has been also carried out to reduce CO₂ emissions and improve energy efficiency.

As a method for controlling three-phase AC motors mounted on electric vehicles, home appliances (for example, air conditioners and washing machines), and the like, so-called vector control has been widely adopted. In the vector control, a motor control apparatus generates a command signal to an inverter, based on feedback control of a d-axis current and a q-axis current defined on d-q coordinates of a rotating Cartesian coordinate system of the motor.
Patent Document 1: PCT International Publication No. WO2013/058282
Patent Document 2: China Patent Application CN 202211040361.X

### SUMMARY OF THE INVENTION

Since feedback control of currents is performed on the d-q coordinates in the motor control apparatus as described above, it is necessary to convert, for example, the U-phase, V-phase, and W-phase currents of a motor detected by such a current detection apparatus as shown in PCT International Publication No. WO2013/058282 to d-axis and q-axis currents. More specifically, in the motor control apparatus, after three phase currents (Iu, Iv, and Iw) detected by the current detection apparatus first are converted to two phase currents (Iα and Iβ) defined in a fixed coordinate system by the Clarke transformation, the two phase currents (Iα and Iβ) are converted to two phase currents (Id and Iq) defined in the d-q coordinate system by the Park transformation using a motor rotation angle θ. Thus, in the vector control using output of a conventional current detection apparatus, it is necessary to perform calculation for converting the three phase currents (Iu, Iv, and Iw) to the two phase currents (Id and Iq) in the motor control apparatus.

Furthermore, China Patent Application CN 202211040361.X by the applicant of the present application describes a technology for, by providing two magnetic detection elements at geometrically determined positions around three phase current lines, trying to directly obtain two phase currents (Iα and Iβ) without performing Clarke transformation by calculation by a computer (such a technology will be hereinafter also referred to as “spatial Clarke transformation”).

In the spatial Clarke transformation shown in China Patent Application CN 202211040361.X, however, the arrangement layout of the three phase current lines and the two magnetic detection elements is limited to a few patterns. Since it is necessary to efficiently arrange various parts in an electric vehicle, it is favorable that the degree of freedom of arrangement layout of magnetic detection elements is as high as possible.

Furthermore, when the installation position of a magnetic detection element deviates from an ideal position, an output value of the magnetic detection element also deviates. In China Patent Application CN 202211040361.X, however, such influence of positional deviation of a magnetic detection element is not considered.

An object of the present invention is to provide a current detection apparatus with high toughness against positional deviation while increasing the degree of freedom of arrangement layout of a plurality of magnetic detection elements and, therefore, contribute to improvement of energy efficiency.
(1) A current detection apparatus according to the present invention (for example, a current detection apparatus 3 described later) is a current detection apparatus for detecting currents flowing through a first phase bus bar (for example, a U-phase bus bar 6u described later), a second phase bus bar (for example, a V-phase bus bar 6v described later), and a third phase bus bar (for example, a W-phase bus bar 6w described later) of a three-phase motor (for example, a motor M described later), the current detection apparatus including: a first magnetic detection element (for example, a first magnetic detection element 81 described later) and a second magnetic detection element (for example, a second magnetic detection element 82 described later) provided around the first, second, and third phase bus bars; a storage (for example, a magnetic sensitivity coefficient storage unit 23 described later) that stores values of a plurality of coefficients (for example, magnetic sensitivity coefficients described later) determined according to relative positions of the first and second magnetic detection elements relative to the first, second, and third phase bus bars; and a two-phase current values calculator (for example, a two-phase current values calculation unit 22 described later) that calculates two-phase current values based on a first output value (for example, an output value Sₓ described later) of the first magnetic detection element, a second output value (for example, an output value S_{y}) of the second magnetic detection element, and the values of the plurality of coefficients, wherein, when values of currents flowing through the first, second, and third phase bus bars are indicated by I1, I2, and I3, the first output value is indicated by S1, and an arbitrary constant other than “−½” is indicated by X, a position of a detection center of the first magnetic detection element and an orientation of a first detection axis (for example, a first detection axis Ox described later) of the first magnetic detection element on a first element arrangement surface (for example, an element arrangement surface P described later) that is orthogonal to the first, second, and third phase bus bars and includes the detection center of the first magnetic detection element are determined such that Formula (1) below is satisfied.

$$S 1 ∝ [ - 1 / 2 X - 1 / 2 ] [ \begin{matrix}I 1 \\ I 2 \\ I 3\end{matrix} ] \qquad ( 1 )$$

(2) In this case, it is preferable that the first, second, and third phase bus bars are arranged on a first virtual line (for example, a first virtual line L1 described later) with the second phase bus bar as a center, on the first element arrangement surface, and the detection center of the first magnetic detection element is arranged on a second virtual line (for example, a second virtual line L2 described later) that is orthogonal to the first virtual line and passes through the second phase bus bar on the first element arrangement surface.
(3) In this case, it is preferable that the first, second, and third phase bus bars are arranged on a third virtual line (for example, the first virtual line L1 described later) with the second phase bus bar as a center, on a second element arrangement surface (for example, the element arrangement surface P described later) that is orthogonal to the first, second, and third phase bus bars and includes a detection center of the second magnetic detection element, and the detection center of the second magnetic detection element is arranged on a fourth virtual line (for example, the third virtual line L3 or a fourth virtual line L4 described later) that is orthogonal to the third virtual line and passes through the first phase bus bar or the third phase bus bar on the second element arrangement surface.
(4) In this case, it is preferable that the first detection axis is arranged parallel to the first virtual line on the first element arrangement surface, and a second detection axis (for example, a second detection axis Oy described later) of the second magnetic detection element is arranged parallel to the third virtual line on the second element arrangement surface.
(5) In this case, it is preferable that the current detection apparatus further includes a third magnetic detection element (for example, a third magnetic detection element 83 described later) provided around the first, second, and third phase bus bars, the first, second, and third phase bus bars are arranged on a third virtual line (for example, the first virtual line L1 described later) with the second phase bus bar as a center, on a second element arrangement surface (for example, the element arrangement surface P described later) that is orthogonal to the first, second, and third phase bus bars and includes a detection center of the second magnetic detection element, the detection center of the second magnetic detection element is arranged on a fourth virtual line (for example, the third virtual line L3 described later) that is orthogonal to the third virtual line and passes through the first phase bus bar on the second element arrangement surface, the first, second, and third phase bus bars are arranged on a fifth virtual line (for example, the first virtual line L1 described later) with the second phase bus bar as a center, on a third element arrangement surface that is orthogonal to the first, second, and third phase bus bars and includes a detection center of the third magnetic detection element, the detection center of the third magnetic detection element is arranged on a sixth virtual line (for example, the fourth virtual line L4 described later) that is orthogonal to the fifth virtual line and passes through the third phase bus bar, on the third element arrangement surface, and a third detection axis (for example, a third detection axis Oz described later) of the third magnetic detection element is arranged parallel to the fifth virtual line on the third element arrangement surface.
(6) In this case, it is preferable that the current detection apparatus further includes a failure determiner (for example, a failure determination unit 25 described later) that determines whether there is a failure or not in each of the first, second, and third magnetic detection elements, and the two-phase current value calculator calculates, when the first magnetic detection element is determined to have failed, the two-phase current values based on the second output value, a third output value of the third magnetic detection element, and the values of the plurality of coefficients, calculates, when the second magnetic detection element is determined to have failed, the two-phase current values based on the first output value, the third output value, and the values of the plurality of coefficients, and calculates, when the third magnetic detection element is determined to have failed, the two-phase current values based on the first output value, the second output value, and the values of the plurality of coefficients.
(1) In a current detection apparatus according to the present invention, currents flowing through three bus bars are detected based on two magnetic detection elements provided around the bus bars. Therefore, according to the present invention, since it is possible to reduce the number of magnetic detection elements in comparison with a conventional current detection apparatus in which one magnetic detection element is provided for each bus bar, costs can be reduced accordingly. Here, as described in Patent Application 2024-017475 by the present applicant, currents obtained by multiplying three-phase currents (I1, I2, I3) the three-phase sum of which is 0 by a transformation matrix (−½, X, −½) described in Formula (1) above is different from currents obtained by multiplying three-phase currents (I1, I2, I3) by components on the first row (−½, 1, −½) of the transformation matrix of Clarke transformation only in amplitude and is the same in phases. Therefore, in the present invention, by determining the position of the detection center of a first magnetic detection element and the orientation of a first detection axis such that Formula (1) above that includes an arbitrary constant other than “−½” is satisfied, it is possible to cause an output value S1 of the first magnetic detection element to be proportional to an α-phase current value obtained by combining currents flowing through the three bus bars at a determined ratio by (the) Clarke transformation. Note that, in the case of X=−½, output values of the first magnetic detection element are constantly 0 for the three-phase currents (I1, I2, I3) the three-phase sum of which is 0 and, therefore, the output values are excluded. Furthermore, the present invention includes: a storage that stores values of a plurality of coefficients determined according to relative positions of the first and second magnetic detection elements relative to the three bus bars; and a two-phase current values calculator that calculates two-phase current values based on output values of the first and second magnetic detection elements and the values of the plurality of coefficients. Therefore, according to the present invention, it is possible to acquire the two-phase current values, which are obtained by performing three-phase/two-phase conversion of three-phase currents flowing through the three bus bars, causing the arrangement layout of the second magnetic detection element between the two magnetic detection elements to be arbitrary, and, therefore, it is possible to increase the degree of freedom of arrangement layout of the two magnetic detection elements.

Furthermore, under the layout described in China Patent Application CN 202211040361.X, an error of a β-axis magnetic detection element, which outputs a value proportional to a β-phase current value, due to positional deviation is larger than that of an α-axis magnetic detection element, which outputs a value proportional to the α-phase current value (that is, the first magnetic detection element in the present invention) as described later with reference to FIG. 4, Therefore, in the present invention, by causing the arrangement layout of the β-axis magnetic detection element with a low toughness against positional deviation to be arbitrary as described above, it is possible to increase both of the degree of freedom of arrangement layout of the two magnetic detection elements and toughness against positional deviation, and, therefore, contribute to improvement of energy efficiency.
(2) In the present invention, the first, second, and third phase bus bars are arranged on a first virtual line with the second phase bus bar as a center, within a first element arrangement surface, and the detection center of the first magnetic detection element is arranged on a second virtual line that is orthogonal to the first virtual line and passes through the second phase bus bar. Thereby, it is possible to arrange the three bus bars compactly and use the first magnetic detection element as an α-axis detection element the output value of which is proportional to the α-phase current value.
(3) In the present invention, the first, second, and third phase bus bars are arranged on a third virtual line with the second phase bus bar as a center, within a second element arrangement surface, and the detection center of the second magnetic detection element is arranged on a fourth virtual line that is orthogonal to the third virtual line and passes through the first or third phase bus bar. Thereby, in the present invention, it is possible to, while securing a distance between the second and first magnetic detection elements along the arrangement direction of the three bus bars, arrange the second magnetic detection element directly above the first or third phase bus bar, and, thereby, it is possible to improve the toughness of the second magnetic detection element against positional deviation.
(4) In the present invention, the first detection axis is arranged parallel to the first virtual line, and a second detection axis is arranged parallel to the third virtual line. That is, both of the first and second detection axes are arranged parallel to the arrangement direction of the three bus bars. Thereby, it is possible to, in comparison with the case where the first and second detection axes are arranged orthogonal to the arrangement direction of the three bus bars, improve the toughness of the magnetic detection elements against positional deviation.
(5) In the present invention, the first, second, and third phase bus bars are arranged on the third virtual line with the second phase bus bar as a center, within the second element arrangement surface, and the detection center of the second magnetic detection element is arranged on the fourth virtual line that is orthogonal to the third virtual line and passes through the first phase bus bar. Furthermore, the first, second, and third phase bus bars are arranged on a fifth virtual line with the second phase bus bar as a center, within a third element arrangement surface, and the detection center of the third magnetic detection element is arranged on a sixth virtual line that is orthogonal to the fifth virtual line and passes through the third phase bus bar. Thereby, in the present invention, it is possible to, while securing distances among the first, second, and third magnetic detection elements along the arrangement direction of the three bus bars, arrange the second and third magnetic detection elements directly above the first and third phase bus bars, respectively, and, therefore, it is possible to improve the toughness of the second and third magnetic detection elements against positional deviation.
(6) In the present invention, when any of the three magnetic detection elements has failed, the two-phase current value calculator calculates the two-phase current values based on output values of the other two magnetic detection elements and the values of the plurality of coefficients stored in the storage. Therefore, according to the present invention, it is possible to, even if any of the three magnetic detection elements has failed, continue acquiring two-phase current values using the other two magnetic detection elements.

### BRIEF DESCRIPTION OF THE DRAWINGS

FIG. 1 is a diagram showing a configuration of a current detection apparatus according to one embodiment of the present invention and an electric vehicle equipped with the current detection apparatus;

FIG. 2 is a diagram schematically showing a configuration of a sensor unit;

FIG. 3 is a diagram schematically showing an example of arrangement of three bus bars and three magnetic detection elements on an element arrangement surface that is orthogonal to the three bus bars; and

FIG. 4 is a diagram schematically showing an α-axis magnetic detection element and a β-axis magnetic detection element described in China Patent Application CN 202211040361.X.

### DETAILED DESCRIPTION OF THE INVENTION

A description will be made below on a current detection apparatus according to one embodiment of the present invention and an electric vehicle mounted with the current detection apparatus, with reference to drawings.

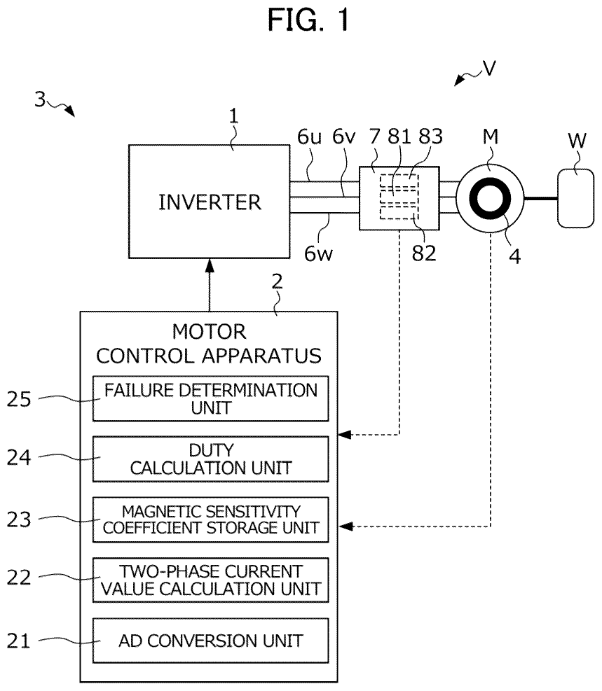

FIG. 1 is a diagram showing a configuration of a current detection apparatus 3 according to the present embodiment and an electric vehicle V equipped with the current detection apparatus 3. Note that, though the description will be made on the case where the current detection apparatus 3 is mounted on the electric vehicle V, the present invention is not limited thereto. The current detection apparatus 3 can be mounted on anything that controls the three-phase motor based on vector control, such as an air conditioner or a washing machine, in addition to the electric vehicle V.

The electric vehicle V includes a three-phase AC motor M (hereinafter simply referred to as “the motor M”), a drive wheel W coupled with the output shaft of the motor M via a power transmission mechanism not shown, an inverter 1 that connects a battery not shown and the motor M, a sensor unit 7 that generates a signal corresponding to a current that flows through the motor M, a resolver 4 that detects a rotation position of the motor M, and a motor control apparatus 2 that controls the inverter 1 based on detection signals of the sensor unit 7 and the resolver 4.

The inverter 1 is, for example, a PWM inverter using pulse width modulation, which is equipped with a bridge circuit configured by bridge connection of a plurality of switching elements (for example, IGBT's), and has a function of converting DC power and AC power. The inverter 1 is connected to the battery on the DC input/output side and connected to each of the U-phase, V-phase, and W-phase coils of the motor M on the AC input/output side, and converts power between the battery and the motor M. By performing on/off driving of the switching element of each phase according to a gate drive signal, which is generated from a gate drive circuit not shown at a predetermined timing, the inverter 1 converts DC power supplied from the battery to AC power to supply the AC power to the motor M or converts AC power supplied from the motor M to DC power to supply the DC power to the battery.

The sensor unit 7 includes three magnetic detection elements 81, 82, and 83 provided around three bus bars (a U-phase bus bar 6u, a V-phase bus bar 6v, and a W-phase bus bar 6w) that connect the motor M and the inverter 1. These magnetic detection elements 81, 82, and 83 generate detection signals corresponding to components of magnetic flux densities of magnetic fields generated by currents flowing through the bus bars 6u, 6v, and 6w, along their respective detection axes. Note that, though the description will be made on the case of providing the three magnetic detection elements 81 to 83 around the three bus bars 6u, 6v, and 6w in the present embodiment, the present invention is not limited thereto. As described below, it is possible to, if at least two of the three magnetic detection elements 81 to 83 exist, acquire two-phase current values (I_{d}, I_{q}) described later, which are required for vector control of the motor M. Note that, in the case of providing only two magnetic detection elements around the three bus bars 6u, 6v, and 6w, it is preferable to make a combination such that at least the first magnetic detection element 81 is included in order to keep detection accuracy as high as possible. That is, it is preferable to combine the first magnetic detection element 81 and the second magnetic detection element 82 or combine the first magnetic detection element 81 and the third magnetic detection element 83.

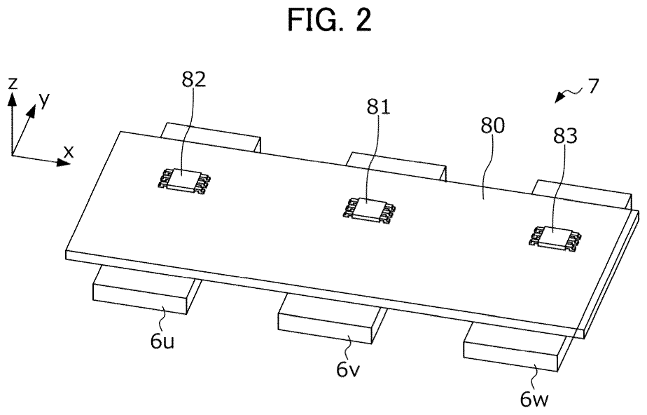

FIG. 2 is a diagram schematically showing a configuration of the sensor unit 7. The sensor unit 7 includes the first magnetic detection element 81, the second magnetic detection element 82, and the third magnetic detection element 83 provided around the three bus bars 6u, 6v, and 6w, and a substrate 80 to which the magnetic detection elements 81 to 83 are fixed. That is, the three magnetic detection elements 81 to 83 are arranged around the three bus bars 6u, 6v, and 6w in a state of being integrated by the substrate 80.

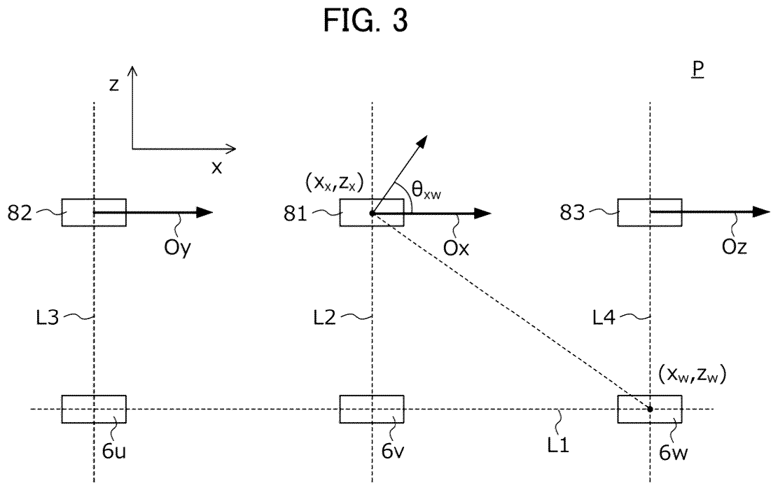

FIG. 3 is a diagram schematically showing an example of arrangement of the three bus bars 6u, 6v, and 6w and the three magnetic detection elements 81 to 83 on an element arrangement surface P that is orthogonal to the three bus bars 6u, 6v, and 6w. Though the description will be made below on a case where detection centers of the three magnetic detection elements 81 to 83 are arranged within the common element arrangement surface P as shown in FIG. 3, the present invention is not limited thereto. For example, the detection centers of the first magnetic detection element 81, the second magnetic detection element 82, and the third magnetic detection element 83 may be arranged on a first element arrangement surface that is orthogonal to the three bus bars 6u, 6v, and 6w, a second element arrangement surface that is orthogonal to the three bus bars 6u, 6v, and 6w and is different from the first element arrangement surface, and a third element arrangement surface that is orthogonal to the three bus bars 6u, 6v, and 6w and is different from the first and second element arrangement surfaces, respectively. Note that, though FIG. 3 shows a case where the three bus bars 6u, 6v, and 6w are arranged in order of the U-phase bus bar 6u, the V-phase bus bar 6v, and the W-phase bus bar 6w on a linear first virtual line L1 at equal intervals within the element arrangement surface P as the most preferable example, the present invention is not limited thereto. The three bus bars 6u, 6v, and 6w need not be linearly arranged, and the intervals among the bus bars 6u, 6v, and 6w need not be equal.

The first magnetic detection element 81 is arranged at such a position that its output value Sₓ is proportional to an α-phase current value I_{α} obtained by performing Clarke transformation of three-phase current values (Iᵤ, Iᵥ, I_{w}). More specifically, as shown in FIG. 3, the detection center of the first magnetic detection element 81 is arranged on a second virtual line L2 that is orthogonal to the first virtual line L1 and passes through the V-phase bus bar 6v on the element arrangement surface P. Furthermore, a first detection axis Ox of the first magnetic detection element 81 is arranged parallel to the arrangement direction of the three bus bars 6u, 6v, and 6w, that is, the first virtual line L1.

In comparison, the second and third magnetic detection elements 82 and 83 are arranged basically at arbitrary positions on the element arrangement surface P. In other words, no matter which positions the two magnetic detection elements 82 and 83 are arranged on the element arrangement surface P, the two-phase current values (I_{d}, I_{q}) required for vector control of the motor M can be acquired. It is, however, favorable that the two magnetic detection elements 82 and 83 are arranged at the positions exemplified in FIG. 3 in order to minimize detection errors and minimize errors due to positional deviation.

More specifically, when a virtual line that is orthogonal to the first virtual line L1 and passes through the U-phase bus bar 6u and a virtual line that is orthogonal to the first virtual line L1 and passes through the W-phase bus bar 6w on the element arrangement surface P are referred to as a third virtual line L3 and a fourth virtual line L4, respectively, it is preferable that each of the detection centers of the second and third magnetic detection elements 82 and 83 is arranged on any of the third virtual line L3 and the fourth virtual line L4. In the present embodiment, the description will be made on a case where the detection center of the second magnetic detection element 82 is arranged on the third virtual line L3, and the detection center of the third magnetic detection element 83 is arranged on the fourth virtual line L4 as shown in FIG. 3. The present invention, however, is not limited thereto. For example, the detection centers of the second and third magnetic detection elements 82 and 83 may be arranged on the fourth and third virtual lines L4 and L3, respectively. By arranging the detection centers of the three magnetic detection elements 81 to 83 at the positions described above, it is possible to arrange the magnetic detection elements 81 to 83 directly above the bus bars 6u, 6v, and 6w, respectively, with the intervals among the magnetic detection elements 81 to 83 along the arrangement direction of the three bus bars 6u, 6v, and 6w being ensured.

Furthermore, it is preferable that a second detection axis Oy of the second magnetic detection element 82 and a third detection axis Oz of the third magnetic detection element 83 are arranged parallel to the first virtual line L1 similarly to the first detection axis Ox, as shown in FIG. 3.

Here, output values (Sₓ, S_{y}, S_{z}) of the three magnetic detection elements 81 to 83 are indicated by Formula (2-1) when magnetic sensitivity coefficient (kₓᵤ, kₓᵥ, k_{xw}) of the first magnetic detection element 81 for the bus bars 6u, 6v, and 6w, respectively, magnetic sensitivity coefficient (k_{yu}, k_{yv}, k_{yw}) of the second magnetic detection element 82 for the bus bars 6u, 6v, and 6w, respectively, and magnetic sensitivity coefficient (k_{zu}, k_{zv}, k_{zw}) of the third magnetic detection element 83 for the bus bars 6u, 6v, and 6w, respectively, are used. The magnetic sensitivity coefficients (kₓᵤ, kₓᵥ, k_{xw}) are values determined by relative positions of the first magnetic detection element 81 relative to the three bus bars 6u, 6v, and 6w, respectively, and the orientation of the first detection axis Ox. The magnetic sensitivity coefficients (k_{yu}, k_{yv}, k_{yw}) are values determined by relative positions of the second magnetic detection element 82 relative to the three bus bars 6u, 6v, and 6w, respectively, and the orientation of the second detection axis Oy. The magnetic sensitivity coefficients (k_{zu}, k_{zv}, k_{zw}) are values determined by relative positions of the third magnetic detection element 83 relative to the three bus bars 6u, 6v, and 6w, respectively, and the orientation of the third detection axis Oz. More specifically, for example, the magnetic sensitivity coefficient k_{xw} of the first magnetic detection element 81 for the W-phase bus bar 6w is defined by Formula (2-2) below according to Ampere's Law. In Formula (2-2) below, u represents magnetic permeability. Furthermore, in Formula (2-2) below, θ_{xw} indicates an angle formed by a magnetic field vector of the W-phase bus bar 6w and the first detection axis Ox of the first magnetic detection element 81; (xₓ, zₓ) indicates coordinate values of the first magnetic detection element 81 on the element arrangement surface P; and (x_{w}, z_{w}) indicates coordinate values of the W-phase bus bar 6w on the element arrangement surface P. Note that, since the other magnetic sensitivity coefficients (kₓᵤ, k_{xw}, k_{yu}, . . . ) are also defined based on Ampere's Law similarly to Formula (2-2) below, detailed description thereof will be omitted.

$$[ \begin{matrix}{S}_{x} \\ {S}_{y} \\ {S}_{z}\end{matrix} ] = [ \begin{matrix}{k}_{xu} & {k}_{xv} & {k}_{xw} \\ {k}_{yu} & {k}_{yv} & {k}_{yw} \\ {k}_{zu} & {k}_{zv} & {k}_{zw}\end{matrix} ] [ \begin{matrix}{I}_{u} \\ {I}_{v} \\ {I}_{w}\end{matrix} ] \qquad ( 2 - 1 )$$

$${k}_{xw} = \frac{μ cos {θ}_{xw}}{2 π \sqrt{{( {x}_{w} - {x}_{x} )}^{2} + {( {z}_{w} - {z}_{x} )}^{2}}} \qquad ( 2 - 2 )$$

Here, the position of the detection center of the first magnetic detection element 81 and the orientation of the first detection axis Ox on the element arrangement surface P are determined such that Formula (3) below is satisfied. When the three bus bars 6u, 6v, and 6w are arranged on the first virtual line L1, the detection center of the first magnetic detection element 81 is arranged on the second virtual line L2, and the first detection axis Ox is arranged in parallel to the first virtual line L1 as described above, it is possible to satisfy Formula (3) below that is defined, including an arbitrary constant X other than “−½”, by adjusting the distance between the detection center of the first magnetic detection element 81 and the V-phase bus bar 6v. Note that Formula (3) below is equivalent to setting the ratio of the three magnetic sensitivity coefficients to kₓᵤ:kₓᵥ:k_{xw}=−½:X:−½.

$${S}_{x} ∝ [ - 1 / 2 X - 1 / 2 ] [ \begin{matrix}{I}_{u} \\ {I}_{v} \\ {I}_{w}\end{matrix} ] \qquad ( 3 )$$

Returning to FIG. 1, the motor control apparatus 2 is a computer that generates a drive signal to the gate drive circuit of the inverter 1 by performing vector control based on detection signals from the sensor unit 7 and the resolver 4, and inputs the drive signal to the gate drive circuit.

In the motor control apparatus 2, an AD conversion unit 21, a two-phase current values calculation unit 22, a magnetic sensitivity coefficient storage unit 23, a duty calculation unit 24, and a failure determination unit 25 are configured as modules related to execution of the vector control described above.

The AD conversion unit 21 acquires the output values (Sₓ, S_{y}, S_{z}) of the three magnetic detection elements 81 to 83 by performing AD conversion of detection signals of the three magnetic detection elements 81 to 83.

The failure determination unit 25 determines whether there is a failure in each of the three magnetic detection elements 81, 82, and 83. The failure determination unit 25 determines whether there is a failure in each of the magnetic detection elements 81 to 83, for example, based on the output values (Sₓ, S_{y}, S_{z}) of the three magnetic detection elements 81 to 83 acquired by the AD conversion unit 21.

By acquiring the two-phase current values (I_{d}, I_{q}) calculated by the two-phase current values calculation unit 22 according to a procedure described later, and a d-axis current command I_{dc} and a q-axis current command I_{qc} corresponding to driving force required by a driver and performing feedback control based on deviations (I_{dc}-I_{d}, I_{qc}-I_{q}) of the current values, the duty calculation unit 24 generates a drive signal for the gate drive circuit of the inverter 1 so as to realize the driving force required by the driver and inputs the drive signal to the gate drive circuit.

The magnetic sensitivity coefficient storage unit 23 stores values of a plurality of magnetic sensitivity coefficients (kₓᵤ, kₓᵥ, k_{xw}, k_{yu}, k_{yv}, k_{yw}, k_{zu}, k_{zv}, k_{zw}) determined according to relative positions of the three magnetic detection elements 81 to 83 relative to the three bus bars 6u, 6v, and 6w.

The two-phase current values calculation unit 22 calculates the two-phase current values (I_{d}, I_{q}) based on at least two of the output values (Sₓ, S_{y}, S_{z}) of the three magnetic detection elements 81 to 83 acquired by the AD conversion unit 21, a rotation position θ of the motor M detected by the resolver 4, and the values of the magnetic sensitivity coefficients stored in the magnetic sensitivity coefficient storage unit 23. Hereinafter, the description will be made on a case where the two-phase current values calculation unit 22 calculates a d-axis current value I_{d} and a q-axis current value I_{q} obtained by performing Clarke transformation and Park transformation of the three-phase current values (Iᵤ, Iᵥ, I_{w}).

First, when the rotation position θ of the motor M is used, conversion from the three-phase current values (Iᵤ, Iᵥ, I_{w}) to the two-phase current values (I_{d}, I_{q}) is generally indicated by Formula (4) below. In Formula (4) below, “B” is a constant, and the value thereof is the square root of ⅔ in the case of absolute conversion and ⅔ in the case of relative conversion.

$$[ \begin{matrix}{I}_{d} \\ {I}_{q}\end{matrix} ] = B [ \begin{matrix}cos θ & cos ( θ - \frac{2}{3} π ) & cos ( θ + \frac{2}{3} π ) \\ - sin θ & - sin θ ( θ - \frac{2}{3} π ) & - sin θ ( θ + \frac{2}{3} π )\end{matrix} ] [ \begin{matrix}{I}_{u} \\ {I}_{v} \\ {I}_{w}\end{matrix} ] \qquad ( 4 )$$

Here, when a matrix of the magnetic sensitivity coefficients defined by Formula (2-1) above is defined as “A” as shown by Formula (5-1) below, Formula (4) above can be rewritten as Formula (5-2) below, using an inverse matrix A⁻¹ of the matrix A. That is, Formula (5-2) below is a conversion formula for converting the output values (Sₓ, S_{y}, S_{z}) of the three magnetic detection elements 81 to 83 into the two-phase values (I_{d}, I_{q}).

$$A = [ \begin{matrix}{k}_{xu} & {k}_{xv} & {k}_{xw} \\ {k}_{yu} & {k}_{yv} & {k}_{yw} \\ {k}_{zu} & {k}_{zv} & {k}_{zw}\end{matrix} ] \qquad ( 5 - 1 )$$

$$[ \begin{matrix}{I}_{d} \\ {I}_{q}\end{matrix} ] = B [ \begin{matrix}cos θ & cos ( θ - \frac{2}{3} π ) & cos ( θ + \frac{2}{3} π ) \\ - sin θ & - sin ( θ - \frac{2}{3} π ) & - sin ( θ + \frac{2}{3} π )\end{matrix} ] {A}^{- 1} [ \begin{matrix}{S}_{x} \\ {S}_{y} \\ {S}_{z}\end{matrix} ] \qquad ( 5 - 2 )$$

When the determinant and cofactor matrix of the matrix A of the magnetic sensitivity coefficients are used, the inverse matrix A⁻¹ with three rows and three columns in Formula (5-2) above is indicated by Formula (6-1) below. Furthermore, the determinant and cofactor matrix of the matrix A are indicated by Formulas (6-2) and (6-3) below when the magnetic sensitivity coefficients are used. Therefore, the values of components of the inverse matrix A⁻¹ in Formula (5-2) above can be calculated based on the values of the magnetic sensitivity coefficients (kₓᵤ, kₓᵥ, k_{xw}, k_{yu}, k_{yv}, k_{yw}, k_{zu}, k_{zv}, k_{zw}) stored in the magnetic sensitivity coefficient storage unit 23.

$${A}^{- 1} = \frac{1}{\vert A \vert} \tilde{A} \qquad ( 6 - 1 )$$

$$\vert A \vert = {k}_{xu} {k}_{yv} {k}_{zw} + {k}_{xv} {k}_{yw} {k}_{zu} + {k}_{xw} {k}_{yu} {k}_{zv} - {k}_{xw} {k}_{yv} {k}_{zu} - {k}_{xv} {k}_{yu} {k}_{zw} - {k}_{xu} {k}_{yw} {k}_{zv} \qquad ( 6 - 2 )$$

$$\tilde{A} = [ \begin{matrix}{k}_{yv} {k}_{zw} - {k}_{yw} {k}_{zv} & - ( {k}_{xv} {k}_{zw} - {k}_{xw} {k}_{zv} ) & {k}_{xv} {k}_{yw} - {k}_{xw} {k}_{yv} \\ - ( {k}_{yu} {k}_{zw} - {k}_{yw} {k}_{zu} ) & {k}_{xu} {k}_{zw} - {k}_{xw} {k}_{zu} & - ( {k}_{xu} {k}_{yw} - {k}_{xw} {k}_{yu} ) \\ {k}_{yu} {k}_{zv} - {k}_{yv} {k}_{zu} & - ( {k}_{xu} {k}_{zv} - {k}_{xv} {k}_{zu} ) & {k}_{xu} {k}_{yv} - {k}_{xv} {k}_{yu}\end{matrix} ] \qquad ( 6 - 3 )$$

The two-phase current values calculation unit 22 calculates the two-phase current values (I_{d}, I_{q}) by inputting the output values (Sₓ, S_{y}, S_{z}) of the three magnetic detection elements 81 to 83, the rotation position θ, and the values of the plurality of magnetic sensitivity coefficients read from the magnetic sensitivity coefficient storage unit 23 into the above conversion formula (5-2).

Note that, though Formula (2-1) above is a conversion formula for converting the three-phase current values (Iᵤ, Iᵥ, I_{w}) into the output values (Sₓ, S_{y}, S_{z}) of the three magnetic detection elements 81 to 83, the conversion formula (2-1) can be rewritten as Formulas (7-1) to (7-3) below when a three-phase sum is 0 (in the case of Iᵤ+Iᵥ+I_{w}=0). That is, Formula (7-1) is a conversion formula for converting the three-phase current values (Iᵤ, Iᵥ, I_{w}) into the output values (Sₓ, S_{y}) of the two magnetic detection elements 81 and 82; Formula (7-2) is a conversion formula for converting the three-phase current values (Iᵤ, Iᵥ, I_{w}) into the output values (Sₓ, S_{z}) of the two magnetic detection elements 81 and 83; and Formula (7-3) is a conversion formula for converting the three-phase current values (Iᵤ, Iᵥ, I_{w}) into the output values (S_{y}, S_{z}) of the two magnetic detection elements 82 and 83.

$$[ \begin{matrix}{S}_{x} \\ {S}_{y} \\ 0\end{matrix} ] = [ \begin{matrix}{k}_{xu} & {k}_{xv} & {k}_{xw} \\ {k}_{yu} & {k}_{yv} & {k}_{yw} \\ 1 & 1 & 1\end{matrix} ] [ \begin{matrix}{I}_{u} \\ {I}_{v} \\ {I}_{w}\end{matrix} ] \qquad ( 7 - 1 )$$

$$[ \begin{matrix}{S}_{x} \\ 0 \\ {S}_{z}\end{matrix} ] = [ \begin{matrix}{k}_{xu} & {k}_{xv} & {k}_{xw} \\ 1 & 1 & 1 \\ {k}_{zu} & {k}_{zv} & {k}_{zw}\end{matrix} ] [ \begin{matrix}{I}_{u} \\ {I}_{v} \\ {I}_{w}\end{matrix} ] \qquad ( 7 - 2 )$$

$$[ \begin{matrix}0 \\ {S}_{y} \\ {S}_{z}\end{matrix} ] = [ \begin{matrix}1 & 1 & 1 \\ {k}_{yu} & {k}_{yv} & {k}_{yw} \\ {k}_{zu} & {k}_{zv} & {k}_{zw}\end{matrix} ] [ \begin{matrix}{I}_{u} \\ {I}_{v} \\ {I}_{w}\end{matrix} ] \qquad ( 7 - 3 )$$

Therefore, according to Formula (7-1) above, by causing all the values of the three magnetic sensitivity coefficients (k_{zu}, k_{zw}, k_{zw}) related to the third magnetic detection element 83 to be “1” (that is, k_{zu}=k_{zv}=k_{zw}=1) in the above conversion formula (5-2), a conversion formula for conversion from the output values (Sₓ, S_{y}) of the first and second magnetic detection elements 81 and 82 to the two-phase current values (I_{d}, I_{q}) can be obtained. Furthermore, according to Formula (7-2) above, by causing all the values of the three magnetic sensitivity coefficients (k_{yu}, k_{yv}, k_{yw}) related to the second magnetic detection element 82 to be “1” (that is, k_{yu}=k_{yv}=k_{yw}=1) in the above conversion formula (5-2), a conversion formula for conversion from the output values (Sₓ, S_{z}) of the first and third magnetic detection elements 81 and 83 to the two-phase current values (I_{d}, I_{q}) can be obtained. Furthermore, according to Formula (7-3) above, by causing all the values of the three magnetic sensitivity coefficients (kₓᵤ, kₓᵥ, k_{xw}) related to the first magnetic detection element 81 to be “1” (that is, kₓᵤ=kₓᵥ=k_{xw}=1) in the above conversion formula (5-2), a conversion formula for conversion from the output values (S_{y}, S_{z}) of the second and third magnetic detection elements 82 and 83 to the two-phase current values (I_{d}, I_{q}) can be obtained.

As described above, the two-phase current values calculation unit 22 can calculate the two-phase current values (I_{d}, I_{q}) based on at least two selected among the output values (Sₓ, S_{y}, S_{z}) of the three magnetic detection elements 81 to 83.

Therefore, the two-phase current values calculation unit 22 selects at least two among the three magnetic detection elements 81 to 83, which have been determined to be normal by the failure determination unit 25, and calculates the two-phase current values (I_{d}, I_{q}) based on the output values of the selected at least two magnetic detection elements.

More specifically, when all the three magnetic detection elements 81 to 83 are determined to be normal, the two-phase current values calculation unit 22 calculates the two-phase current values (I_{d}, I_{q}) based on the output values (Sₓ, S_{y}, S_{z}) of all the three magnetic detection elements 81 to 83, the output values (Sₓ, S_{y}) of the first and second magnetic detection elements 81 and 82, or the output values (Sₓ, S_{z}) of the first and third magnetic detection elements 81 and 83. Thus, it is favorable that, in order to keep the detection accuracy as high as possible, the two-phase current values calculation unit 22 calculates the two-phase current values (I_{d}, I_{q}) by a combination including at least the output value of the first magnetic detection element 81.

When the first magnetic detection element 81 is determined to have failed, and the second and third magnetic detection elements 82 and 83 are determined to be normal, the two-phase current values calculation unit 22 calculates the two-phase current values (I_{d}, I_{q}) based on the output values (S_{y}, S_{z}) of the second and third magnetic detection elements 82 and 83.

When the second magnetic detection element 82 is determined to have failed, and the first and third magnetic detection elements 81 and 83 are determined to be normal, the two-phase current values calculation unit 22 calculates the two-phase current values (I_{d}, I_{q}) based on the output values (Sₓ, S_{z}) of the first and third magnetic detection elements 81 and 83.

Furthermore, when the third magnetic detection element 83 is determined to have failed, and the first and second magnetic detection elements 81 and 82 are determined to be normal, the two-phase current values calculation unit 22 calculates the two-phase current values (I_{d}, I_{q}) based on the output values (Sₓ, S_{y}) of the first and second magnetic detection elements 81 and 82.

According to the current detection apparatus 3 according to the present embodiment, the following effects are obtained:
(1) In the current detection apparatus 3 according to the present embodiment, currents flowing through the three bus bars 6u, 6v, and 6w are detected based on at least the two magnetic detection elements 81 and 82 provided around the bus bars 6u, 6v, and 6w. Therefore, according to the present embodiment, since it is possible to reduce the number of magnetic detection elements in comparison with a conventional current detection apparatus in which one magnetic detection element is provided for each bus bar, costs can be reduced accordingly. Here, as described in Patent Application 2024-017475 by the present applicant, currents obtained by multiplying three-phase currents (I1, I2, I3) the three-phase sum of which is 0 by a transformation matrix (−½, X, −½) described in Formula (1) above is different from currents obtained by multiplying three-phase currents (I1, I2, I3) by components on the first row (−½, 1, −½) of the transformation matrix of Clarke transformation only in amplitude and is the same in phases. Therefore, in the present embodiment, it is possible to, by determining the position of the detection center of the first magnetic detection element 81 and the orientation of the first detection axis Ox such that Formula (3) above is satisfied, cause the output value Sₓ of the first magnetic detection element 81 to be proportional to the α-phase current value I_{α} which is obtained by combining currents flowing through the three bus bars 6u, 6v, and 6w at a determined ratio by Clarke transformation. Furthermore, the current detection apparatus 3 of the present embodiment includes the magnetic sensitivity coefficient storage unit 23 storing values of a plurality of magnetic sensitivity coefficients determined according to relative positions of the first and second magnetic detection elements 81 and 82 relative to the three bus bars 6u, 6v, and 6w; and the two-phase current values calculation unit 22 calculating two-phase current values (I_{d}, I_{q}) based on the output values Sₓ and S_{y} of the first and second magnetic detection elements 81 and 82, and the values of the plurality of magnetic sensitivity coefficients. Therefore, according to the present embodiment, it is possible to acquire the two-phase current values (I_{d}, I_{q}), which are obtained by performing three-phase/two-phase conversion of three-phase currents flowing through the three bus bars 6u, 6v, and 6w, causing the arrangement layout of the second magnetic detection element 82 between the two magnetic detection elements 81 and 82 to be arbitrary, and, therefore, it is possible to increase the degree of freedom of arrangement layout of the two magnetic detection elements 81 and 82.

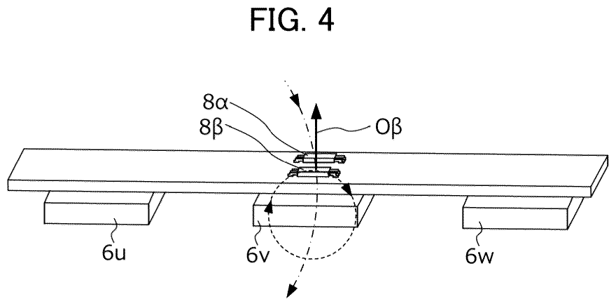

FIG. 4 is a diagram schematically showing an α-axis magnetic detection element 8α and a β-axis magnetic detection element 8β described in China Patent Application CN 202211040361.X. In the invention described in China Patent Application CN 202211040361.X, the two magnetic detection elements 8α and 8β are arranged such that output values thereof are proportional to the α-phase current value I_{α} and the β-phase current value I_{β}, which are obtained by combining currents flowing through the three bus bars 6u, 6v, and 6w at a determined ratio by Clarke transformation, respectively. Note that the α-axis magnetic detection element 8α is arranged at the same position as the first magnetic detection element 81 according to the present embodiment. Furthermore, as shown in FIG. 4, when the three bus bars 6u, 6v, and 6w are arranged side by side, it is necessary to arrange the β-axis magnetic detection element 8β directly above the V-phase bus bar 6v. Furthermore, in the case of causing the output value of the β-axis magnetic detection element 8B to be proportional to the β-phase current value I_{β}, it is necessary to set the magnetic sensitivity coefficient of the β-axis magnetic detection element 8β for the V-phase bus bar 6v to 0. Therefore, it is necessary to arrange a detection axis OB of the β-axis magnetic detection element 8β such that it is orthogonal to the arrangement direction of the three bus bars 6u, 6v, and 6w as shown in FIG. 4.

The detection axis Oβ of the β-axis magnetic detection element 8β described above, however, is orthogonal to a magnetic flux (see a broken line in FIG. 4) concentrically formed around the V-phase bus bar 6v only directly above the V-phase bus bar 6v. Therefore, if the detection center of the β-axis magnetic detection element 8β positionally deviates along the arrangement direction of the three bus bars 6u, 6v, and 6w, the magnetic sensitivity coefficient of the β-axis magnetic detection element 8β for the V-phase bus bar 6v becomes non-zero. Furthermore, since a magnetic flux (see a dash-dotted line in FIG. 4) concentrically formed around the U-phase bus bar 6u is approximately parallel to the detection axis Oβ, change of the magnetic sensitivity coefficient of the β-axis magnetic detection element 8β for the V-phase bus bar 6v, due to positional deviation is larger than change of the magnetic sensitivity coefficient of the α-axis magnetic detection element 8α for the V-phase bus bar 6v, due to positional deviation. Therefore, an error of the β-axis magnetic detection element 8β, which outputs a value proportional to a β-phase current value, due to positional deviation is larger than that of the α-axis magnetic detection element 8α which outputs a value proportional to an α-phase current value (that is, the first magnetic detection element 81 in the present embodiment). In comparison, in the present embodiment, by causing the arrangement layout of the second magnetic detection element 82 to be arbitrary, without adopting the β-axis magnetic detection element 8β with low toughness against positional deviation, it is possible to increase both of the degree of freedom of arrangement layout of the two magnetic detection elements 81 and 82 and toughness against positional deviation, and, therefore, contribute to improvement of energy efficiency.
(2) In the present embodiment, the three bus bars 6u, 6v, and 6w are arranged on the first virtual line L1 with the V-phase bus bar 6v as a center, within the element arrangement surface P, and the detection center of the first magnetic detection element 81 is arranged on the second virtual line L2 that is orthogonal to the first virtual line L1 and passes through the V-phase bus bar 6v. Thereby, it is possible to arrange the three bus bars 6u, 6v, and 6w compactly and use the first magnetic detection element 81 as an α-axis magnetic detection element the output value of which is proportional to an α-phase current value.
(3) In the present embodiment, the detection center of the second magnetic detection element 82 is arranged on the third virtual line L3 or the fourth virtual line L4 that is orthogonal to the first virtual line L1 and passes through the U-phase bus bar 6u or the W-phase bus bar 6w. Thereby, in the present embodiment, it is possible to, while securing a distance between the second and first magnetic detection elements 82 and 81 along the arrangement direction of the three bus bars 6u, 6v, and 6w, arrange the second magnetic detection element 82 directly above the U-phase bus bar 6u or the W-phase bus bar 6w, and, thereby, it is possible to improve the toughness of the second magnetic detection element 82 against positional deviation.
(4) In the present embodiment, the first detection axis Ox is arranged parallel to the first virtual line L1, and the second detection axis Oy is arranged parallel to the first virtual line L1. That is, both of the first and second detection axes Ox and Oy are arranged parallel to the arrangement direction of the three bus bars 6u, 6v, and 6w. Thereby, it is possible to, in comparison with the case where the first and second detection axes ox and Oy are arranged orthogonal to the arrangement direction of the three bus bars 6u, 6v, and 6w, improve the toughness of the magnetic detection elements 81 and 82 against positional deviation.
(5) In the present embodiment, the detection center of the second magnetic detection element 82 is arranged on the third virtual line L3 that is orthogonal to the first virtual line L1 and passes through the U-phase bus bar 6u. Furthermore, the detection center of the third magnetic detection element 83 is arranged on the fourth virtual line L4 that is orthogonal to the first virtual line L1 and passes through the W-phase bus bar 6w. Thereby, in the present embodiment, it is possible to, while securing distances among the first, second, and third magnetic detection elements 81, 82, and 83 along the arrangement direction of the three bus bars 6u, 6v, and 6w, arrange the second and third magnetic detection elements 82 and 83 directly above the U-phase bus bar 6u and the W-phase bus bar 6w, respectively, and, therefore, it is possible to improve the toughness of the second and third magnetic detection elements 82 and 83 against positional deviation.
(6) In the present invention, if any of the three magnetic detection elements 81, 82, and 83 has failed, the two-phase current values calculation unit 22 calculates the two-phase current values based on output values of the other two magnetic detection elements and the values of the plurality of magnetic sensitivity coefficients stored in the magnetic sensitivity coefficient storage unit 23. Therefore, according to the present embodiment, it is possible to, even if any of the three magnetic detection elements 81, 82, and 83 has failed, continue acquiring two-phase current values using the other two magnetic detection elements.

Though one embodiment of the present invention has been described above, the present invention is not limited thereto. A detailed configuration may be appropriately changed within the spirit of the present invention.

What is claimed is:

1. A current detection apparatus for detecting currents flowing through a first phase bus bar, a second phase bus bar, and a third phase bus bar of a three-phase motor, the current detection apparatus comprising:
a first magnetic detection element and a second magnetic detection element provided around the first, second, and third phase bus bars;
a storage that stores values of a plurality of coefficients determined according to relative positions of the first and second magnetic detection elements relative to the first, second, and third phase bus bars; and
a two-phase current values calculator that calculates two-phase current values based on a first output value of the first magnetic detection element, a second output value of the second magnetic detection element, and the values of the plurality of coefficients, wherein
when values of currents flowing through the first, second, and third phase bus bars are indicated by I1, I2, and I3, the first output value is indicated by S1, and an arbitrary constant other than “−½” is indicated by X, a position of a detection center of the first magnetic detection element and an orientation of a first detection axis of the first magnetic detection element on a first element arrangement surface that is orthogonal to the first, second, and third phase bus bars and includes the detection center of the first magnetic detection element are determined such that Formula (1) below is satisfied.
$$S 1 ∝ [ - 1 / 2 X - 1 / 2 ] [ \begin{matrix}I 1 \\ I 2 \\ I 3\end{matrix} ] . \qquad ( 1 )$$

2. The current detection apparatus according to claim 1, wherein
the first, second, and third phase bus bars are arranged on a first virtual line with the second phase bus bar as a center, on the first element arrangement surface, and
the detection center of the first magnetic detection element is arranged on a second virtual line that is orthogonal to the first virtual line and passes through the second phase bus bar on the first element arrangement surface.

3. The current detection apparatus according to claim 2, wherein
the first, second, and third phase bus bars are arranged on a third virtual line with the second phase bus bar as a center, on a second element arrangement surface that is orthogonal to the first, second, and third phase bus bars and includes a detection center of the second magnetic detection element, and
the detection center of the second magnetic detection element is arranged on a fourth virtual line that is orthogonal to the third virtual line and passes through the first phase bus bar or the third phase bus bar on the second element arrangement surface.

4. The current detection apparatus according to claim 3, wherein
the first detection axis is arranged parallel to the first virtual line on the first element arrangement surface, and
a second detection axis of the second magnetic detection element is arranged parallel to the third virtual line on the second element arrangement surface.

5. The current detection apparatus according to claim 1, further comprising a third magnetic detection element provided around the first, second, and third phase bus bars, wherein
the first, second, and third phase bus bars are arranged on a third virtual line with the second phase bus bar as a center, on a second element arrangement surface that is orthogonal to the first, second, and third phase bus bars and includes a detection center of the second magnetic detection element, and
the detection center of the second magnetic detection element is arranged on a fourth virtual line that is orthogonal to the third virtual line and passes through the first phase bus bar on the second element arrangement surface,
the first, second, and third phase bus bars are arranged on a fifth virtual line with the second phase bus bar as a center, on a third element arrangement surface that is orthogonal to the first, second, and third phase bus bars and includes a detection center of the third magnetic detection element,
the detection center of the third magnetic detection element is arranged on a sixth virtual line that is orthogonal to the fifth virtual line and passes through the third phase bus bar, on the third element arrangement surface, and
a third detection axis of the third magnetic detection element is arranged parallel to the fifth virtual line on the third element arrangement surface.

6. The current detection apparatus according to claim 5, further comprising a failure determiner that determines whether there is a failure or not in each of the first, second, and third magnetic detection elements, wherein
the two-phase current value calculator
calculates, when the first magnetic detection element is determined to have failed, the two-phase current values based on the second output value, a third output value of the third magnetic detection element, and the values of the plurality of coefficients,
calculates, when the second magnetic detection element is determined to have failed, the two-phase current values based on the first output value, the third output value, and the values of the plurality of coefficients, and
calculates, when the third magnetic detection element is determined to have failed, the two-phase current values based on the first output value, the second output value, and the values of the plurality of coefficients.

7. The current detection apparatus according to claim 2, further comprising a third magnetic detection element provided around the first, second, and third phase bus bars, wherein
the first, second, and third phase bus bars are arranged on a third virtual line with the second phase bus bar as a center, on a second element arrangement surface that is orthogonal to the first, second, and third phase bus bars and includes a detection center of the second magnetic detection element, and
the detection center of the second magnetic detection element is arranged on a fourth virtual line that is orthogonal to the third virtual line and passes through the first phase bus bar on the second element arrangement surface,
the first, second, and third phase bus bars are arranged on a fifth virtual line with the second phase bus bar as a center, on a third element arrangement surface that is orthogonal to the first, second, and third phase bus bars and includes a detection center of the third magnetic detection element,
the detection center of the third magnetic detection element is arranged on a sixth virtual line that is orthogonal to the fifth virtual line and passes through the third phase bus bar, on the third element arrangement surface, and
a third detection axis of the third magnetic detection element is arranged parallel to the fifth virtual line on the third element arrangement surface.

8. The current detection apparatus according to claim 7, further comprising a failure determiner that determines whether there is a failure or not in each of the first, second, and third magnetic detection elements, wherein
the two-phase current value calculator
calculates, when the first magnetic detection element is determined to have failed, the two-phase current values based on the second output value, a third output value of the third magnetic detection element, and the values of the plurality of coefficients,
calculates, when the second magnetic detection element is determined to have failed, the two-phase current values based on the first output value, the third output value, and the values of the plurality of coefficients, and
calculates, when the third magnetic detection element is determined to have failed, the two-phase current values based on the first output value, the second output value, and the values of the plurality of coefficients.
